(19) United States
(12) Patent Application Publication
(10) Pub. No.: US 2013/0128177 A1
(43) Pub. Date: May 23, 2013

(54) Frame Type Backplane, Backlight Module, and LCD Device

(71) Applicants: Yicheng Kuo, Guangdong (CN); Yuchun Hsiao, Guangdong (CN); Chong Huang, Guangdong (CN); Jiahe Cheng, Guangdong (CN); Chengwen Que, Guangdong (CN); Quan Li, Guangdong (CN); Liuyang Yang, Guangdong (CN)

(72) Inventors: Yicheng Kuo, Guangdong (CN); Yuchun Hsiao, Guangdong (CN); Chong Huang, Guangdong (CN); Jiahe Cheng, Guangdong (CN); Chengwen Que, Guangdong (CN); Quan Li, Guangdong (CN); Liuyang Yang, Guangdong (CN)

(73) Assignee: SHENZEN CHINA STAR OPTOELECTRONICS TECHNOLOGY CO, LTD., Shenzhen, Guangdong (CN)

(21) Appl. No.: 13/375,948

(22) PCT Filed: Nov. 29, 2011
(86) PCT No.: PCT/CN2011/083184

§ 371 Date: Dec. 2, 2011

(30) Foreign Application Priority Data
Nov. 18, 2011 (CN) 201110369622.8

(51) Int. Cl. G02F 1/13357; H05K 7/18; G09F 13/04

(52) U.S. Cl. 349/58; 362/97.1; 211/26

(57) ABSTRACT

The present invention discloses a frame type backplane, a backlight module, and an LCD device. The frame type backplane comprises a frame, and the frame comprises multiple mutually joined brackets. Each bracket is provided with a solid stiffener in the joining position. By research, the inventor finds that: in the backplane formed by joining brackets, when the backplane produces buckling stress, the stress is collected in the joining position of each the bracket. Therefore, the buckling deformation of the backplane usually appears in the joining positions. Because the present invention is provided with solid stiffener(s) in the joining position of two brackets, the bend resistance capacity of the joining position is improved, and then the strength of the whole backplane is improved.

### TECHNICAL FIELD

The present invention relates to the field of liquid crystal displays (LCDs), and more particularly to a frame type backplane, a backlight module, and an LCD device.

### BACKGROUND

An LCD device includes an LCD panel and a backlight module, wherein the bottom of the backlight module is provided with a backplane used for sealing the module and fixing a component in the module. In the existing backplanes, integral backplanes are used and are integrally formed in the mode of metal stamping or plastic injection, causing heavy products and high material cost of the products. For large-size backplanes, because larger stamping equipment is needed, the cost is higher, and because the corresponding die size is large and the structure is complicated, the die cost is also very high. With increasingly fierce market competition, it is more and more important to effectively reduce the design cost. As a result, the key research direction of each designer lies in saving the material cost and simplifying the assembly technology.

An existing backplane, the design of hollowing or joining the backplane is developed on basis of the integral backplane design, and then the cost is reduced to a certain extent; however, the strength of the backplane is reduced due to joining or hollowing, so that it is difficult to fix a printed circuit board (PCB) (originally fixed on the backplane) on the backplane.

### SUMMARY

The aim of the present invention is to provide a high-strength frame type backplane, a backlight module, and an LCD device.

The aim of the present invention is achieved by the following technical schemes.

A frame type backplane comprises a frame, and the frame comprises multiple mutually joined brackets. Each bracket is provided with a solid stiffener in the joining position.

Preferably, the bracket positioned on one side of the frame is provided with a solid lug boss in the joining position to form the solid stiffener; the bracket positioned on the other side of the frame is provided with a groove matched with the solid stiffener in the joining position; after the two brackets are joined, the solid stiffener is embedded in the groove. This is a specific stiffener in the joining position, the stiffener on one side of the joining position is a solid lug boss, and the other side of the joining position is a groove. Thus, the lug boss is embedded in the groove when the two brackets are joined, and the thickness in the joining position is not added when the joining strength of the two brackets is added.

Preferably, both sides of the groove are respectively provided with a solid groove wall to form the solid stiffener. The groove walls at both ends of the groove are of solid structures, so that the joining strength of the two brackets can be further improved.

Preferably, the bracket positioned on one side of the frame is integrally provided with a solid lug boss, which is equivalent that the solid stiffener penetrates through the whole bracket, so that the strength of the bracket is greatly improved, and the backplane is tightly fixed.

Preferably, the brackets positioned on both sides of the frame are respectively provided with a solid lug boss to form the solid stiffener. Thus, the two brackets are joined by two planes in the joining position, and the flatness of the joining position is high.

Preferably, the cross section of the stiffener is a trapezoid in shape. This is a specific stiffener shape.

A backlight module comprises an aforementioned frame type backplane.

An LCD device comprises an aforementioned backlight module.

By research, the inventor finds that: in the backplane formed by joining brackets, when the backplane produces buckling stress, the stress is collected in the joining position of each bracket. Therefore, the buckling deformation of the backplane usually appears in the joining position. Because the present invention is provided with solid stiffener(s) in the joining position of two brackets, the bend resistance capacity of the joining position is greatly improved, and then the strength of the whole backplane is improved.

### BRIEF DESCRIPTION OF FIGURES

FIG. 1 is a schematic diagram of a frame type backplane of the present invention;

FIG. 2 is a schematic diagram of a hollow stiffener;

FIG. 3 is a schematic diagram of a solid stiffener in one joining position of example 1 of the present invention;

FIG. 4 is a schematic diagram of a solid stiffener in the other joining position of example 1 of the present invention; and

FIG. 5 is a schematic diagram of a solid stiffener in the joining position of example 2 of the present invention.

Wherein: 100. frame; 110. bracket; 111. upper bracket; 112. right bracket; 113. lower bracket; 114. left bracket; 115. middle bracket; 120. bridge; 510. lug boss; 520. groove; 530 groove wall.

### DETAILED DESCRIPTION

The present invention will further be described in detail in accordance with the figures and the preferred examples.

As shown in FIG. 1, an LCD device comprises an LCD panel and a backlight module, wherein the bottom of the backlight module is provided with a frame type backplane. The frame type backplane comprises a frame 100 composed of a plurality of brackets 110; the frame 100 is provided with a plurality of bridges 120. As shown in FIG. 1, the bracket 110 comprises an upper bracket 111, a lower bracket 113, a left bracket 114 and a right bracket 112 which are connected end to end to form a large frame 100 of the whole backplane; the large frame 100 is also internally provided with two middle brackets 115; both ends of the middle brackets 115 are respectively fixed on the upper and the lower brackets 110. A plurality of bridges 120 are arranged on each bracket 110 and between the two brackets 110, and the bridges 120 are used for fixing the PCB and other components of the backlight module.

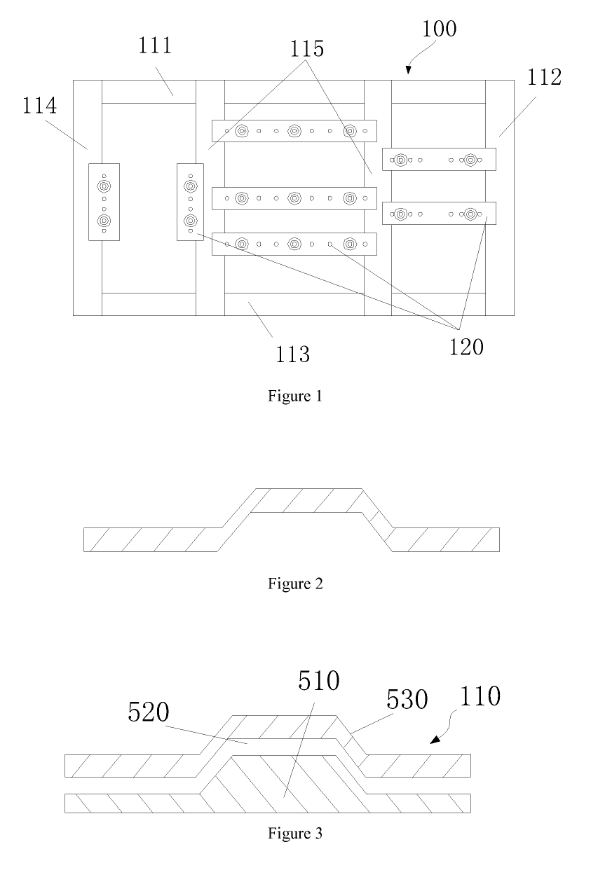

To improve the bend resistance capacity of the brackets 110, each bracket 110 is provided with a stiffener. As shown in FIG. 2, the stiffener is directly stamped on the bracket 110 to form a hollow trapezoid shape. The hollow stiffener already has sufficient strength for guaranteeing the strength of the bracket 110 in the field of LCDs. However, in practical application, through research, the inventor finds that: the buckling stress acting on the joined frame 100 type backplane is mainly collected in the joining position of the two brackets 110. Thus, the stress of the brackets 110 in the joining position is much larger than that in other parts. Therefore, the present invention uses the solid stiffener in the joining position. The solid stiffener will further be described in detail in accordance with the specific examples.

### EXAMPLE 1

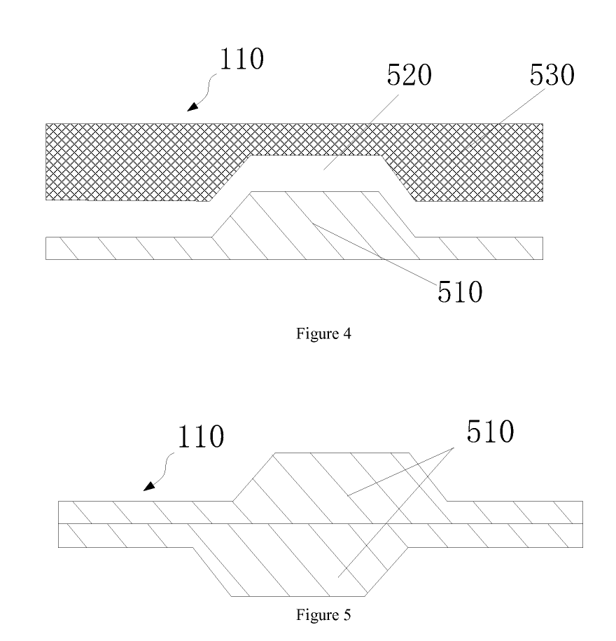

As shown in FIG. 3 and FIG. 4, the bracket 110 positioned on one side of the frame 100 is provided with a solid lug boss 510 in the joining position to form the solid stiffener; the bracket 110 positioned on the other side of the frame 100 is provided with a groove 520 matched with the solid stiffener in the joining position; after the two brackets are joined, the solid stiffener is embedded in the groove. Thus, the lug boss 510 is embedded in the groove 520 when the two brackets 110 are joined, and the thickness in the joining position is not added when the joining strength of the two brackets 110 is added. Furthermore, both sides of the groove 520 are respectively provided with a solid groove wall 530 to form the solid stiffener, as shown in FIG. 4. The groove walls at both ends of the groove 520 are of solid structures, so that the joining strength of the two brackets 110 can be further improved.

Of course, the aforementioned solid lug boss 510 can penetrate through the whole bracket 110, so that the strength of the bracket 110 is greatly improved, and the joined backplane is tightly fixed.

The stiffener can use the current trapezoid shape, and can use other shapes as well. All the shapes can achieve the example effect of the present invention.

### EXAMPLE 2

As shown in FIG. 5, the brackets 110 positioned on both sides of the frame 100 are respectively provided with a solid lug boss 510 to form the solid stiffener. Thus, the two brackets 110 are joined by two planes in the joining position, and the flatness of the joining position is high.

Similarly, the aforementioned solid lug boss 510 can penetrate through the whole bracket 110, so that the strength of the bracket 110 is greatly improved, and the joined backplane is tightly fixed.

The stiffener can use the current trapezoid shape, and can use other shapes as well. All the shapes can achieve the example effect of the present invention.

The solid stiffener may be not suitably made in the stamping mode as the hollow stiffener. After being stamped, even the solid stiffener is formed by reprocessing in the hollow region, the binding strength between the solid stiffener and the hollow stiffener is poor. The solid stiffener of the present invention is preferably made in the modes such as extrusion molding and the like; if the brackets are made of plastic material, the solid stiffener can be made in the modes such as injection molding and the like.

The present invention is described in detail in accordance with the above contents with the specific preferred examples. However, this invention is not limited to the specific embodiments. For the ordinary technical personnel of the technical field of the present invention, on the premise of keeping the conception of the present invention, the technical personnel can also make simple deductions or replacements, and all of which should be considered to belong to the protection scope of the present invention.

We claim:

1. A frame type backplane, comprising: a frame. The frame comprises multiple mutually joined brackets. Each bracket is provided with a solid stiffener in the joining position.

2. The frame type backplane of claim 1, wherein said bracket positioned on one side of the frame is provided with lug boss in the joining position to form said solid stiffener; said bracket positioned on the other side of the frame is provided with a groove matched with said solid stiffener in the joining position; after the two brackets are joined, the solid stiffener is embedded in the groove.

3. The frame type backplane of claim 2, wherein both sides of the groove are respectively provided with a solid groove wall to form said solid stiffener.

4. The frame type backplane of claim 2, wherein said bracket positioned on one side of the frame is integrally provided with a lug boss.

5. The frame type backplane of claim 1, wherein said brackets positioned on both sides of the frame are respectively provided with a solid lug boss in the joining position to form said solid stiffener.

6. The frame type backplane of claim 1, wherein the cross section of said stiffener is trapezoid in shape.

7. A backlight module, comprising the frame type backplane of claim 1. Said frame type backplane comprises a frame, and said frame comprises multiple mutually joined brackets. Each said bracket is provided with a solid stiffener in the joining position.

8. The backlight module of claim 7, wherein said bracket positioned on one side of the frame is provided with a solid lug boss in the joining position to form said solid stiffener; said bracket positioned on the other side of the frame is provided with a groove matched with said solid stiffener in the joining position, after the two brackets are joined, said solid stiffener is embedded in said groove.

9. The backlight module of claim 8, wherein both sides of said groove are respectively provided with a solid groove wall to form said solid stiffener.

10. The backlight module of claim 8, wherein said bracket positioned on one side of the frame is integrally provided with a solid lug boss.

11. The backlight module of claim 7, wherein said brackets positioned on both sides of the frame are respectively provided with a solid lug boss in the joining position to form said solid stiffener.

12. The backlight module of claim 7, wherein the cross section of said stiffener is trapezoid in shape.

13. An LCD device, comprising the backlight module of claim 7. Said backlight module comprises a frame type backplane, said frame type backplane comprises a frame, and said frame comprises multiple mutually joined brackets. Each said bracket is provided with a solid stiffener in the joining position.

14. The LCD device of claim 13, wherein said bracket positioned on one side of the frame is provided with a solid lug boss in the joining position to form said solid stiffener; said bracket positioned on the other side of the frame is provided with a groove matched with said solid stiffener in the joining position; after the two brackets are joined, said solid stiffener is embedded in said groove.

15. The LCD device of claim 14, wherein both sides of the groove are respectively provided with a solid groove wall to form said solid stiffener.

16. The LCD device of claim 14, wherein said bracket positioned on one side of the frame is integrally provided with a solid lug boss.

17. The LCD device of claim 13, wherein said brackets positioned on both sides of the frame are respectively provided with a solid lug boss in the joining position to form said solid stiffener.

18. The LCD device of claim 13, wherein the cross section of said stiffener is trapezoid in shape.
